(19) United States
(12) Patent Application Publication
(10) Pub. No.: US 2015/0270417 A1
(43) Pub. Date: Sep. 24, 2015

(54) DEPOSITION PROCESS FOR SOLAR CELL FRONT CONTACT

(71) Applicant: TSMC Solar Ltd., Taichung City (TW)

(72) Inventor: Yi-Feng HUANG, Kaohsiung City (TW)

(73) Assignee: TSMC Solar Ltd., Taichung City (TW)

(21) Appl. No.: 14/217,528

(22) Filed: Mar. 18, 2014

(51) Int. Cl. H01L 31/0224; H01L 31/072; H01L 31/0336; H01L 31/18

(52) U.S. Cl. CPC H01L 31/022433; H01L 31/1884; H01L 31/072; H01L 31/0336

(57) ABSTRACT

A method includes depositing an acid over a portion of a buffer layer of a solar cell substrate. A front contact material is deposited over the buffer layer, such that the front contact material does not bond to the portion of the buffer layer having the acid on it. Thus, the front contacts of adjacent solar cells of the solar cell substrate are formed with a separation between them.

### PRIORITY CLAIM AND CROSS-REFERENCE

None.

### BACKGROUND

This disclosure related to fabrication of thin film photovoltaic cells.

Solar cells are electrical devices for generation of electrical current from sunlight by the photovoltaic (PV) effect. Thin film solar cells have one or more layers of thin films of PV materials deposited on a substrate. The film thickness of the PV materials can be on the order of nanometers or micrometers.

Examples of thin film PV materials used as absorber layers in solar cells include copper indium gallium selenide (CIGS) and cadmium telluride. Absorber layers absorb light for conversion into electrical current. Solar cells also include front and back contact layers to assist in light trapping and photo-current extraction and to provide electrical contacts for the solar cell. The front contact typically comprises a transparent conductive oxide (TCO) layer. The TCO layer transmits light through to the absorber layer and conducts current in the plane of the TCO layer. In some systems, a plurality of solar cells are arranged adjacent to each other, with the front contact of each solar cell conducting current to the next adjacent solar cell. Each solar cell includes an interconnect structure for conveying charge carriers from the front contact of a solar cell to the back contact of the next adjacent solar cell on the same panel. The interconnect structure reduces the area available for photon collection.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view of a solar cell substrate, in accordance with some embodiments.

FIG. 1B is a cross sectional view of the solar cell substrate of FIG. 1A, in accordance with some embodiments.

FIG. 2A is a plan view of the solar cell substrate of FIG. 1B with an acid line formed thereon, in accordance with some embodiments.

FIG. 2B is a cross sectional view of the solar cell substrate of FIG. 2A, in accordance with some embodiments.

FIG. 3A is a plan view of the solar cell substrate of FIG. 2B with the front contact formed thereon, in accordance with some embodiments.

FIG. 3B is a cross sectional view of the solar cell substrate of FIG. 3A, in accordance with some embodiments.

FIG. 4 is a flow chart of a method in accordance with some embodiments.

FIGS. 5A to 5C show examples of methods for performing step 410 of FIG. 4, in accordance with some embodiments.

FIG. 6A is a scanning electron microscope image of a transparent conductive oxide (TCO) material of a substrate in accordance with some embodiments.

FIG. 6B is a scanning electron microscope image of exposed absorber material on the substrate of FIG. 6A, in a region where TCO bonding is prevented by depositing acid on the region.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure and the accompanying drawings, like reference numerals indicate like items, unless expressly stated to the contrary.

Some embodiments described herein provide methods of forming a P3 line which separates front contacts of adjacent solar cells within the same solar panel. The methods use deposition steps without mechanical scribing. In some embodiments, the front contact is formed by selective chemical vapor deposition (CVD) to form the P3 line.

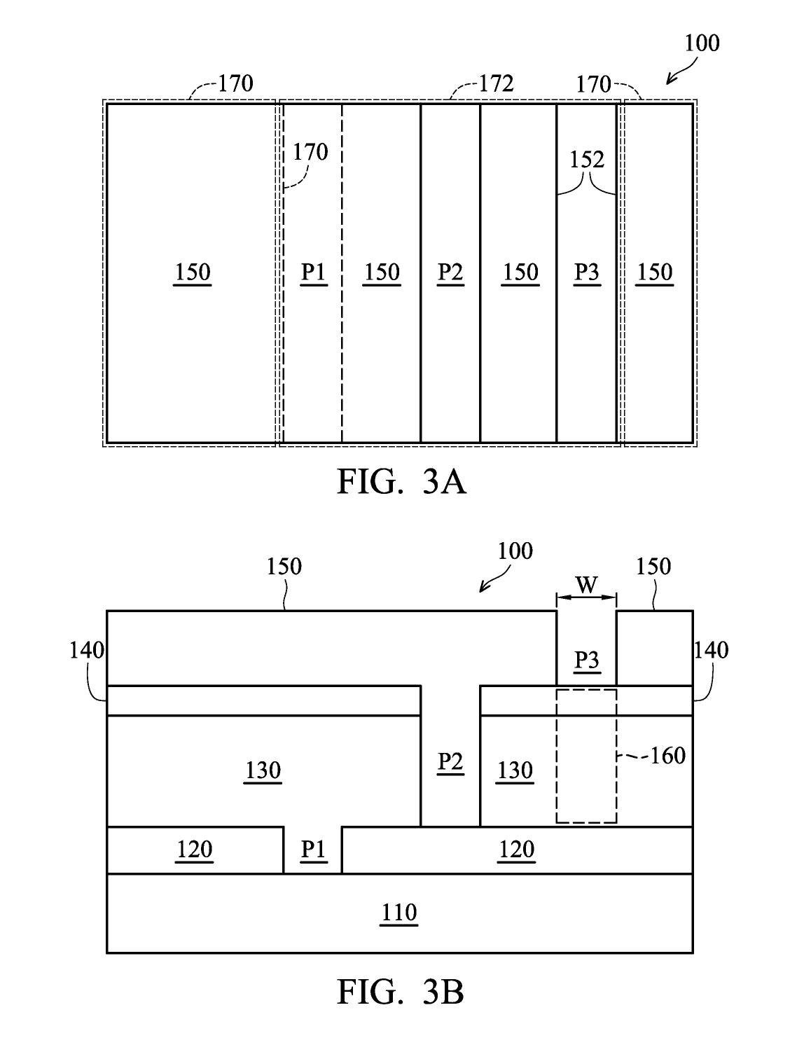

FIGS. 3A and 3B show the solar panel 100 as it is configured after front contact formation, in accordance with some embodiments. The portion of the solar panel 100 shown in FIGS. 3A and 3B includes an interconnect structure 172, which provides a series connection between two adjacent solar cells of the panel 100. In FIGS. 3A and 3B, the width of the interconnect structure 172 is exaggerated relative to the width of the collection region 170 for clarity, but the collection region 170 is actually much wider than the interconnect structure 172.

The solar cell 100 includes a solar cell substrate 110, a back contact layer 120, an absorber layer 130, a buffer layer 140 and a front contact layer 150.

Substrate 110 can include any suitable substrate material, such as glass. In some embodiments, substrate 110 includes a glass substrate, such as soda lime glass, or a flexible metal foil or polymer (e.g., a polyimide, polyethylene terephthalate (PET), polyethylene naphthalene (PEN)). Other embodiments include still other substrate materials.

Back contact layer 120 includes any suitable back contact material, such as metal. In some embodiments, back contact layer 120 can include molybdenum (Mo), platinum (Pt), gold (Au), silver (Ag), nickel (Ni), or copper (Cu). Other embodiments include still other back contact materials. In some embodiments, the back contact layer 120 is from about 50 nm to about 2 μm thick.

In some embodiments, absorber layer 130 includes any suitable absorber material, such as a p-type semiconductor. In some embodiments, the absorber layer 130 can include a chalcopyrite-based material comprising, for example, Cu(In,Ga)Se₂ (CIGS), cadmium telluride (CdTe), CulnSe₂ (CIS), CuGaSe₂ (CGS), Cu(In,Ga)Se₂ (CIGS), Cu(In,Ga)(Se,S)₂ (CIGSS), CdTe or amorphous silicon. Other embodiments include still other absorber materials. In some embodiments, the absorber layer 140 is from about 0.3 μm to about 8 μm thick.

Buffer layer 140 includes any suitable buffer material, such as n-type semiconductors. In some embodiments, buffer layer 140 can include cadmium sulphide (CdS), zinc sulphide (ZnS), zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the buffer layer 140 is from about 1 nm to about 500 nm thick.

In some embodiments, front contact layer 150 includes an annealed transparent conductive oxide (TCO) layer of constant thickness of about 100 nm or greater. The terms “front contact” and “TCO layer” are used interchangeably herein; the former term referring to the function of the layer 150, and the latter term referring to its composition. In some embodiments, the charge carrier density of the TCO layer 150 can be from about 1×10¹⁷ cm⁻³ to about 1×10¹⁸ cm⁻³. The TCO material for the annealed TCO layer can include suitable front contact materials, such as metal oxides and metal oxide precursors. In some embodiments, the TCO material can include AZO, GZO, AGZO, BZO or the like) AZO: alumina doped ZnO; GZO: gallium doped ZnO; AGZO: alumina and gallium co-doped ZnO; BZO: boron doped ZnO. In other embodiments, the TCO material can be cadmium oxide (CdO), indium oxide (In₂O₃), tin dioxide (SnO₂), tantalum pentoxide (Ta₂O₅), gallium indium oxide (GaInO₃), (CdSb₂O₃), or indium oxide (ITO). The TCO material can also be doped with a suitable dopant.

In some embodiments, in the doped TCO layer 150, SnO₂ can be doped with antimony, (Sb), flourine (F), arsenic (As), niobium (Nb) or tantalum (Ta). In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO₂ can be doped with antimony (Sb), F, As, niobium (Nb), or tantalum (Ta). In other embodiments, In₂O₃ can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants.

The layers 120, 130, 140 and 150 are provided in the collection regions 170. Solar cell 100 also includes an interconnect structure 172 that includes three lines, referred to as P1, P2, and P3. The P1 scribe line extends through the back contact layer 130 and is filled with the absorber layer material. The P2 scribe line extends through the buffer layer 140 and the absorber layer 130, and contacts the back contact 120 of the next adjacent solar cell. The P3 line extends through the front contact layer 150, but not the buffer layer 140 or absorber layer 130. The P3 line of the adjacent solar cell is immediately to the left of the solar cell collection region 170.

The P3 line separates the front contacts 150 of adjacent solar cells, so that each front contact can transmit current through the P2 scribe line to the back contact of the next adjacent solar cell without shorting between front adjacent contacts. The front contact layer 150 has a respective P3 line (separation region) in each solar cell, in which the absorber layer 130 and buffer layer 140 are continuous beneath the P3 separation region, but no front contact (TCO) material is present in the separation region. In the configuration of FIGS. 3A and 3B, the absorber layer 130 and buffer layer 140 are formed in a region 160 below the P3 line. This provides additional photon collection area, reducing the non-collecting “dead zone” in the interconnect structure 172. Charge carriers generated at the p-n junction within the region 160 flow to the adjacent collection region 170 (to the right in FIG. 3B) and are collected by the front contact of the adjacent cell.

In some embodiments, the P3 separation region has a width W smaller than 100 micrometers. In some embodiments, the P3 separation region has a width W of about 70 micrometers. This width is about 100 micrometers smaller than a corresponding width of a P3 scribe line achieved by mechanical scribing. Because a solar panel can include about 100 solar cells (each with a respective P3 line), the total savings in P3 line width is about 100×100 μm=10,000 μm=1 cm. This corresponds to an increase of 1 cm in the length of the collection area, or an increase of 55 cm² for a solar panel having 100 solar cells with a panel width of 55 cm.

Also, because the front contact 150 is formed by deposition processes without and material removal step, the TCO material has an edge 152 without cracks on each side of the separation region. TCO material removal methods, such as mechanical scribing can cause cracks in the TCO material, but the front contact layer 150 described herein is free of cracks.

Further, because there is no concern about crack formation during P3 line formation, the P3 line can be located closer to the P2 scribe line without risk of a crack adjacent the P3 line propagating to the edge of the P2 line. Thus, additional reduction in the width of the interconnect structure 172 can be achieved.

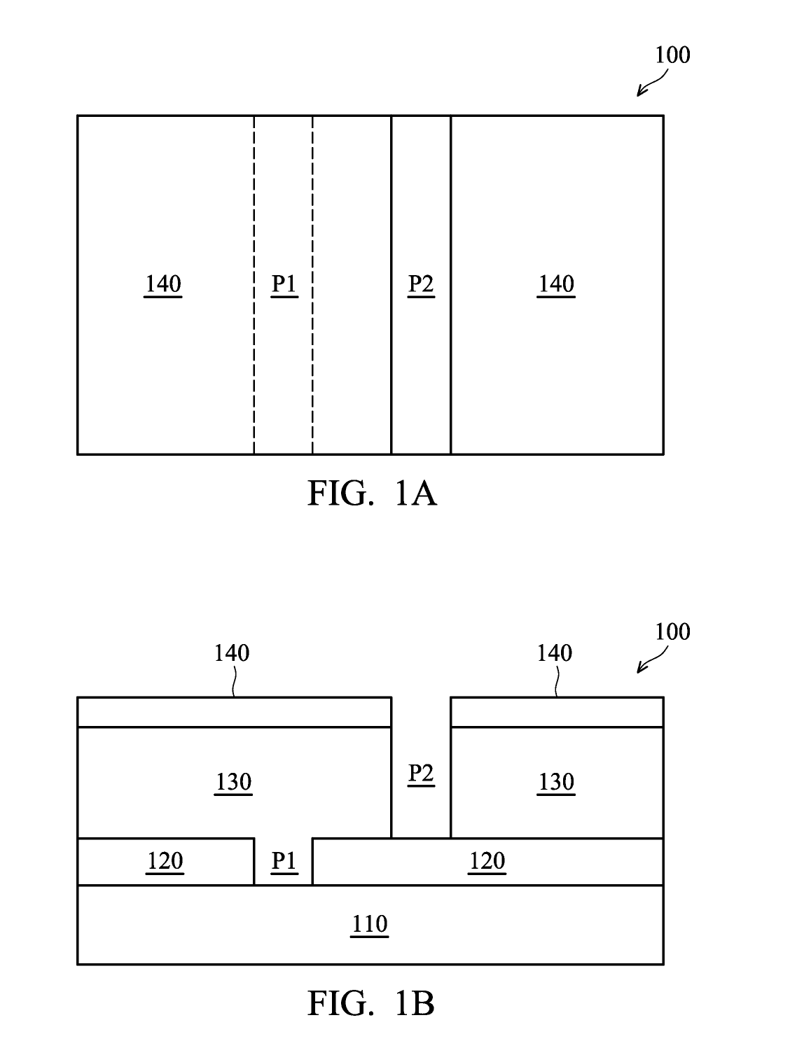

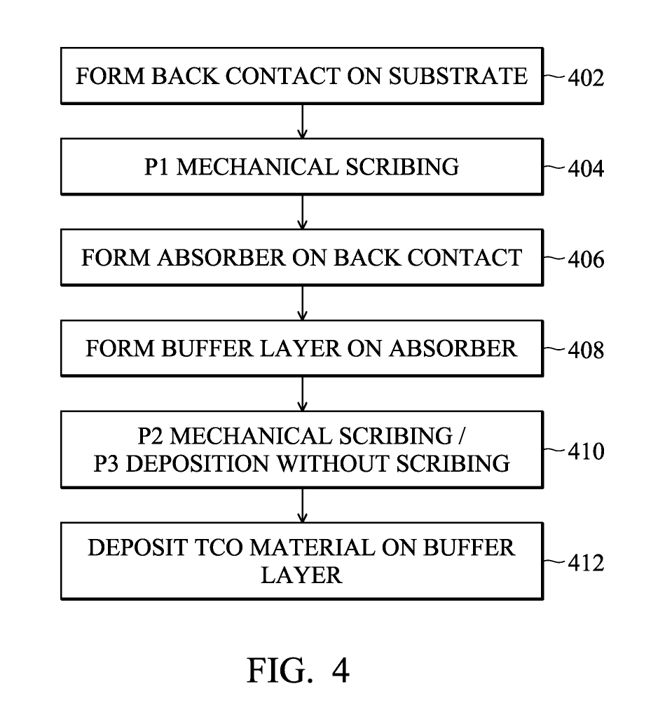

FIG. 4 is a flow chart of a method of forming the solar cell of FIGS. 3A to 3B. FIGS. 1A to 3B show steps in the formation of a solar panel 100.

At step 402, the back contact 120 is formed over the solar cell substrate 110. The back contact can deposited by PVD, for example sputtering, of a metal such as Mo, Cu or Ni over the substrate, or by CVD or ALD or other suitable techniques.

At step 404, the P1 scribe line is formed through the back contact layer 120. For example, the scribe line can be formed by mechanical scribing, or by a laser or other suitable scribing process. Each solar cell in the panel 100 has a respective P1 scribe line.

At step 406, an absorber layer 130 is formed over the back contact layer 120. The absorber layer 130 can be deposited by PVD (e.g., sputtering), CVD, ALD, electro deposition or other suitable techniques. For example, a CIGS absorber layer can be formed by sputtering a metal film comprising copper, indium and gallium then applying a selenization process to the metal film.

At step 408, the buffer layer 140 is formed over the absorber layer 130. The buffer layer 140 can be deposited by chemical deposition (e.g., chemical bath deposition), PVD, ALD, or other suitable techniques.

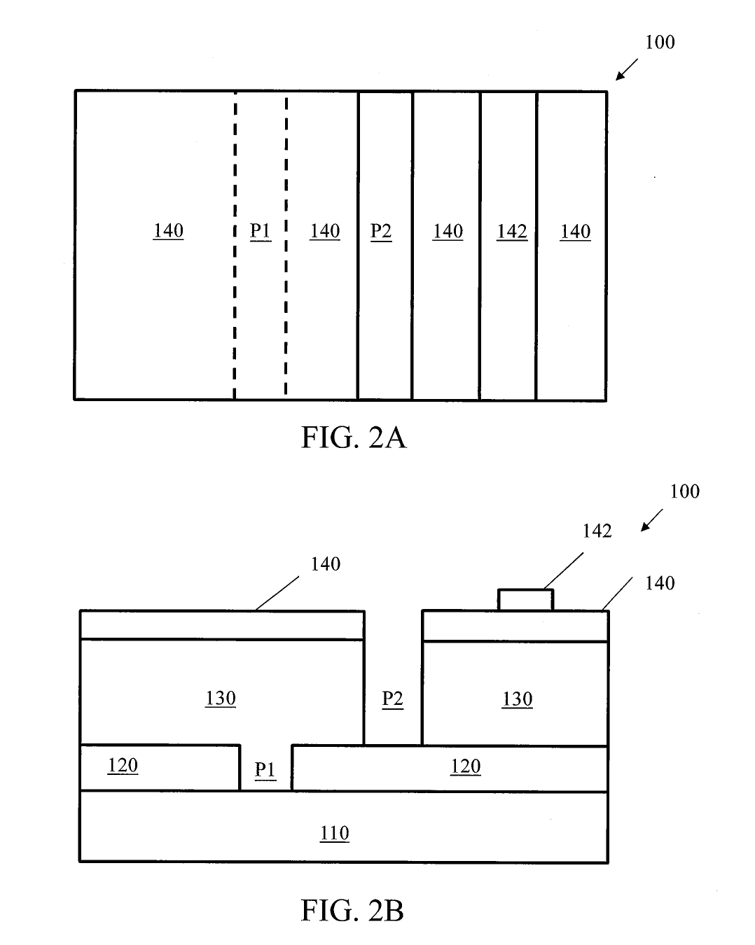

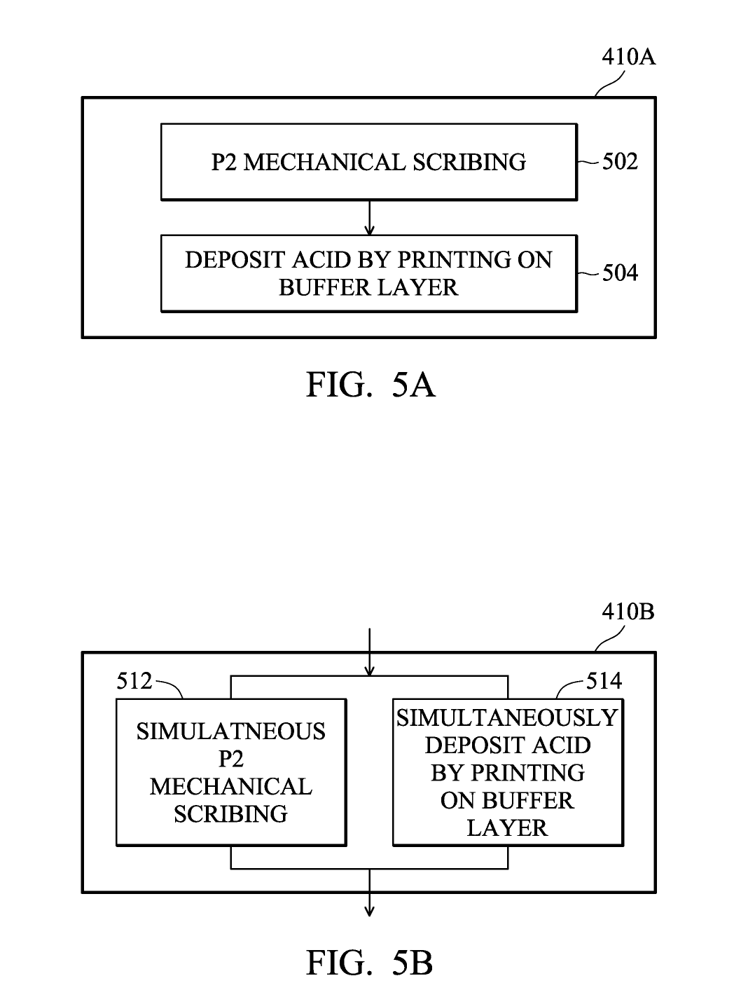

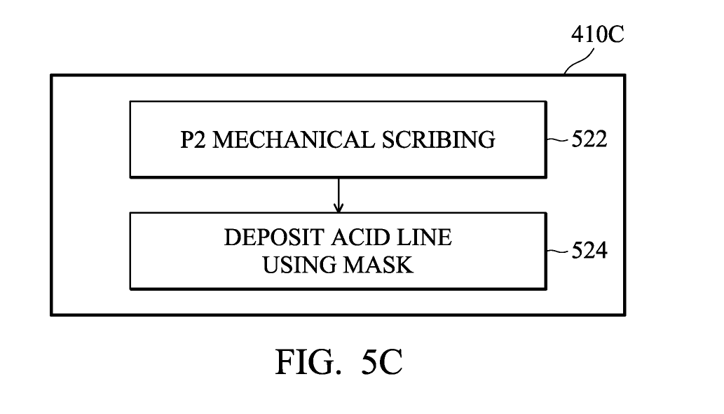

At step 410, the P2 scribe line is formed and a P3 deposition is performed without scribing the P3 line. This step is discussed below in the description of FIGS. 5A to 5C. The configuration of the substrate at the conclusion of this step is shown in FIGS. 2A and 2B.

At step 412, the front contact layer 150 is formed over the buffer layer 140, which is over the absorber layer 130. This step includes depositing a front contact material (TCO) over the buffer layer 140, such that the front contact material does not bond to the portion of the buffer layer having the acid 142 thereon, thereby forming front contacts of adjacent solar cells of the solar cell substrate with a separation therebetween.

In some embodiments, the step of depositing the front contact material comprises chemical vapor deposition (CVD), such as metal organic chemical vapor deposition (MOCVD). In other embodiments, the front contact material is deposited by low pressure chemical vapor deposition (LPCVD) or by plasma enhanced chemical vapor deposition (PECVD).

The front contact material (TCO) is deposited over the buffer layer, such that the front contact material does not bond to the portion of the buffer layer 140 having the acid 142 thereon. Front contacts of adjacent solar cells of the solar cell substrate are thus formed with a separation between them, without requiring any mechanical scribing.

In some embodiments, no P3 material removal step is performed. In some embodiments, following the TCO deposition, the acid solution evaporates from the P3 line without requiring any cleaning step. In some embodiments, where an additive (such as silicon oxide particles) is included in the acid, the silicon acid can remain in the P3 line after TCO deposition. Thus, in some embodiments, additives in the acid solution 142 can be volatile, while in other embodiments, the additives can be transparent and non-conductive, and can be allowed to remain in the P3 line after front contact formation. A transparent, non-conductive material will not interfere with photon collection, nor form a bridge between adjacent front contacts 150. Thus, allowing a transparent, non-conductive additive to remain in the P3 line after front contact formation does not interfere with solar panel performance or efficiency.

FIG. 5A shows a method 410A of performing step 410, in accordance with some embodiments.

The method 410A includes sequential formation of the P2 scribe line, and P3 deposition.

At step 502, the P2 scribe line can be formed by mechanical scribing, or by a laser or other suitable scribing process. The configuration of the substrate at the conclusion of this step is shown in FIGS. 1A and 1B.

At step 504, an acid 142 is deposited over a portion of the buffer layer 140. In some embodiments, the step of depositing the acid 142 includes printing the acid on the buffer layer using a printing head of a scribing tool. The printing head is one of a number of commercially available devices which can be mounted behind the mechanical tip of the scribing tool. In this example, the printing step 504 is performed sequentially after the P2 scribing step 502. In other embodiments, the P2 scribing step is performed sequentially after the printing.

The acid 142 can be any acid solution which prevents TCO deposition or bonding between the TCO material and the underlying absorber or buffer material, but does not etch the underlying absorber or buffer material. In some embodiments, the acid solution is a volatile liquid, so that following TCO deposition, any remaining acid evaporates without requiring any special cleaning process. In some embodiments, the acid comprises HCl or H₂SO₄. For example, in some embodiments, the absorber layer is CIGS, the buffer layer 140 comprises ZnO, and the acid is a solution of HCl in water, with a concentration of the HCl in a range from about 0.2 mol to about 1.0 mol. In other embodiments, an HCl solution is used to prevent deposition of an SnO TCO material on a ZnO buffer layer. An appropriate acid solution can be selected for any other combination of buffer layer material and TCO material.

In some embodiments, the acid 142 further comprises an additive for controlling spreading of the acid, for example, by controlling the surface tension of the solution. For example, in some embodiments, the additive comprises silicon oxide particles. The additive prevents the line of acid 142 from spreading and increasing the width W of the P3 line.

FIG. 5B show a variation of the acid depositing process 410B, wherein the printing is performed while a P2 scribe line is being mechanically scribed in the solar cell substrate, where the P2 scribe line penetrates the buffer layer and absorber layer of the solar cell substrate.

At step 512, the P2 scribe line is scribed.

At step 514, the acid is deposited simultaneously by printing on the buffer layer. The acid solution can be the same as described above for the example of FIG. 5A. The scribing tool is configured to scribe the P2 line and, at the same time, print a line of the acid solution. Because step 514 deposits the acid at the same time as the existing P2 scribing process, the total process time that would be spent performing P3 scribing is eliminated. For a solar panel having about 100 P3 lines, each about 55 cm in length, this results in a reduction in total process time (for fabricating a solar panel) of about 50 seconds.

FIG. 5C shows another example of a process for forming the P2 scribe line and the P3 deposition.

At step 522, the P2 scribe line is formed by mechanical scribing, or by a laser or other suitable scribing process. The configuration of the substrate at the conclusion of this step is shown in FIGS. 1A and 1B.

At step 522, the P3 line formed using a mask (not shown). For example, a mask can be placed over the solar cell substrate, where the mask has openings in the form of lines corresponding to the P3 lines. The the acid 142 can be sprayed over the entire mask, but is only deposited on the buffer layer 140 in the P3 regions. In some embodiments, a single nozzle applies the spray and scans along the length of each P3 line, sequentially. In other embodiments, a plurality of nozzles are arranged in a line, for spraying the acid along an entire P3 line, so each individual P3 line can be sprayed along its length all at once. In other embodiments, a two dimensional array of nozzles is provided, for spraying the entire solar panel simultaneously.

The configuration of the substrate at the conclusion of any of the processes 410A, 410B or 410C is as shown in FIGS. 2A and 2B.

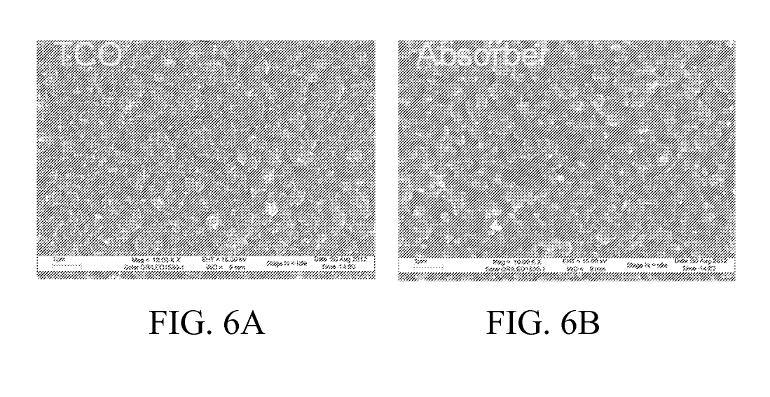

FIGS. 6A and 6B are scanning electron microscope images taken from two portions of a substrate. FIG. 6A shows the crystalline structure of a ZnO TCO layer. FIG. 6B shows the crystalline structure of an exposed absorber layer material. The substrate was processed by depositing a solution of HCl in water on the portion of the substrate shown in FIG. 6B, and then subjecting the entire substrate to the MOCVD gas. The region shown in FIG. 6B has larger rougher crystals indicating the absorber material, whereas the region on which the TCO bonded to the buffer layer (as shown in FIG. 6A) has smaller, more triangular crystals.

The selective deposition process described herein can be used not only for the P3 line, but also for any post CVD process pattern. It also can be used for any display or touch panel post CVD process pattern.

Using the methods describe herein, the P3 line, which separates front contacts of adjacent solar cells within the same solar panel, is formed by deposition steps without mechanical scribing. The method eliminates “chipout,” the excess scribe line width that results from mechanical scribing techniques. A narrower P3 line is provided, increasing the absorber area available for photon collection, and reducing the size of the “dead zone” in the interconnect structure. The resulting front contacts have edges adjacent the P3 line, which are free from cracks because the P3 line is formed without mechanical scribing. Also, in some embodiments, the P3 line can be located closer to the P2 scribe line, reducing the spacing from P1 to P3, thus providing additional reduction in the width of the interconnect structure 172, and additional increase in the area available for photon collection.

In some embodiments, a method comprises: depositing an acid over a portion of a buffer layer of a solar cell substrate; and depositing a front contact material over the buffer layer, such that the front contact material does not bond to the portion of the buffer layer having the acid thereon, thereby forming front contacts of adjacent solar cells of the solar cell substrate with a separation therebetween.

In some embodiments, a method comprises: forming a back contact over a solar cell substrate; forming an absorber over the back contact; forming a buffer layer over the absorber; depositing an acid over a portion of the buffer layer; and depositing a front contact material over the buffer layer, such that the front contact material does not bond to the portion of the buffer layer having the acid thereon, thereby forming front contacts of adjacent solar cells of the solar cell substrate with a separation therebetween.

In some embodiments, a solar panel comprises: a solar cell substrate; a back contact over the solar cell substrate; an absorber over the back contact; a buffer layer over the absorber; and a front contact material over the buffer layer. The front contact layer has at least one separation region in which the absorber layer and buffer layer are continuous beneath the separation region, but no front contact material is present in the separation region. The separation region separates front contacts of adjacent solar cells. The separation region has a width smaller than 100 micrometers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
depositing an acid over a portion of a buffer layer of a solar cell substrate; and
depositing a front contact material over the buffer layer, such that the front contact material does not bond to the portion of the buffer layer having the acid thereon, thereby forming front contacts of adjacent solar cells of the solar cell substrate with a separation therebetween.

2. The method of claim 1, wherein the step of depositing the acid includes printing the acid on the buffer layer.

3. The method of claim 2, wherein the printing is performed using a printing head of a scribing tool.

4. The method of claim 2, wherein the printing is performed while a P2 scribe line is being mechanically scribed in the solar cell substrate, the P2 scribe line penetrating the buffer layer and an absorber layer of the solar cell substrate.

5. The method of claim 1, wherein the separation is a P3 line of the solar cell substrate, and the P3 line is formed without mechanical scribing.

6. The method of claim 1, wherein the acid is deposited using a mask.

7. The method of claim 1, wherein the step of depositing the front contact material comprises chemical vapor deposition.

8. A method comprising:
forming a back contact over a solar cell substrate;
forming an absorber over the back contact;
forming a buffer layer over the absorber;
depositing an acid over a portion of the buffer layer; and
depositing a front contact material over the buffer layer, such that the front contact material does not bond to the portion of the buffer layer having the acid thereon, thereby forming front contacts of adjacent solar cells of the solar cell substrate with a separation therebetween.

9. The method of claim 8, wherein the step of depositing the acid includes printing the acid on the buffer layer using a printing head of a scribing tool.

10. The method of claim 9, wherein the printing is performed while a P2 scribe line is being mechanically scribed in the solar cell substrate, the P2 scribe line penetrating the buffer layer and absorber layer of the solar cell substrate.

11. The method of claim 10, wherein the separation is a P3 line of the solar cell substrate, and the P3 line is formed without mechanical scribing.

12. The method of claim 8, wherein the acid is deposited using a mask.

13. The method of claim 8, wherein the step of depositing the front contact material comprises metal organic chemical vapor deposition.

14. The method of claim 8, wherein the acid comprises HCl or H₂SO₄.

15. The method of claim 14, wherein the buffer layer comprises ZnO, and the acid is solution of HCl in water, with a concentration of the HCl in a range from about 0.2 mol to about 1.0 mol.

16. The method of claim 14, wherein the acid further comprises an additive for controlling spreading of the acid.

17. The method of claim 16, wherein the additive comprises silicon oxide particles.

18-20. (canceled)

21. A method comprising:
forming a back contact over a solar cell substrate;
forming an absorber over the back contact;
forming a buffer layer over the absorber;
depositing an acid over a portion of the buffer layer; and
depositing a front contact material over the buffer layer, such that the front contact material does not bond to the portion of the buffer layer having the acid thereon, thereby forming a separation opening that extends from a top surface of the front contact material to a top surface of the buffer material.

22. The method of claim 21, wherein the step of depositing the acid includes printing the acid on the buffer layer using a printing head of a scribing tool.

23. The method of claim 9, wherein the printing is performed while a P2 scribe line is being mechanically scribed in the solar cell substrate, the P2 scribe line penetrating the buffer layer and absorber layer of the solar cell substrate.
